(19) United States
(12) Patent Application Publication
(10) Pub. No.: US 2007/0004218 A1
(43) Pub. Date: Jan. 4, 2007

(54) Method of cleaning a semiconductor device and method of manufacturing a semiconductor device using the same

(75) Inventors: Keum-Joo Lee, Hwaseong-si (KR); Jin-Hye Bae, Suwon-si (KR); In-Seak Hwang, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd

(21) Appl. No.: 11/476,746

(22) Filed: Jun. 29, 2006

(30) Foreign Application Priority Data
Jun. 30, 2005 (KR) 10-2005-0057487

(51) Int. Cl. H01L 21/302

(52) U.S. Cl. 438/756; 438/745

(57) ABSTRACT

Example embodiments of the present invention relate to a method of cleaning a semiconductor device and a method of manufacturing a semiconductor device using the same. Other example embodiments of the present invention relate to a method of cleaning a semiconductor device by removing a residual organic compound and a method of manufacturing a semiconductor device using the same. An oxide layer including an opening may be formed on a substrate. A conductive layer may be formed in the opening. The oxide layer may be removed using an etching solution including an organic compound. A residual organic compound adhered to the substrate and the conductive layer may be removed using an ozone solution. The residual organic compound and an etching residue may be removed by the cleaning process using the ozone solution.

### PRIORITY STATEMENT

This application claims the benefit of priority under 35 USC § 119 from Korean Patent Application No. 2005-57487, filed on Jun. 30, 2005, the contents of which are herein incorporated by references in their entirety.

### BACKGROUND OF THE INVENTION

1. Field of the Invention

Example embodiments of the present invention relate to a method of cleaning a semiconductor device and a method of manufacturing a semiconductor device using the same. Other example embodiments of the present invention relate to a method of cleaning a semiconductor device by removing a residual organic compound and a method of manufacturing a semiconductor device using the same.

2. Description of the Related Art

A dynamic random access memory (DRAM) device in a semiconductor device may generally include an access transistor and a storage capacitor as a unit cell. As semiconductor devices become more highly integrated, a size of the storage capacitor may be reduced. It has become desirous to manufacture a capacitor having a smaller size and/or a higher capacitance.

The capacitance of the capacitor may be generally represented by Equation (1):
C=(ε₀)(ε)(A/d) Equation (1)
wherein ε₀ represents a vacuum dielectric constant, ε represents a dielectric constant of a dielectric layer relative to the vacuum dielectric constant, A represents an effective area of a lower electrode and d represents a thickness of the dielectric layer.

As shown in Equation (1), in order to increase the capacitance, the effective area of the lower electrode may be increased, a thickness of the dielectric layer may be reduced and/or a high-k material may be used as the dielectric layer. For example, the lower electrode may be formed in a cylindrical shape in order to increase the effective area of the lower electrode. The lower electrode formed in the cylindrical shape may have a higher height relative to a width of the lower electrode.

Examples of a method of manufacturing a capacitor having a cylindrical shape are acknowledged by the prior art.

According to conventional methods of manufacturing a capacitor, an insulation layer including a pad may be formed on a substrate. A lower electrode may be formed in a cylindrical shape on the insulation layer. The lower electrode may have a larger aspect ratio and may be arranged adjacent to another lower electrode. The lower electrode may be electrically connected to the pad.

When forming the lower electrode having the cylindrical shape, a mold layer pattern including an opening may be formed. For example, a lower electrode layer may be conformably formed, or form-fitted, on the mold layer pattern in the opening. The lower electrode layer may be partially removed such that the lower electrode layer is separated into a unit cell. The mold layer pattern may be removed to form the lower electrode in the cylindrical shape. The mold layer pattern may be formed using an oxide. When the mold layer pattern is removed by a dry etching process, then the mold layer pattern may not be completely or substantially removed. An etching residue of the mold layer pattern may remain on the substrate. The mold layer pattern may be removed by a wet etching process using an etching solution (e.g., a low ammonium liquid (LAL) solution) including water, hydrogen fluoride, ammonium fluoride, water and/or a surfactant.

When the mold layer pattern is removed by the wet etching process, impurities may be generated on a surface of the lower electrode. A defect (e.g., a two-bit fail) may form due to adjacent lower electrodes electrically connected to each other. After the etching process, a dry process may be performed using isopropyl alcohol. Impurities may form when an organic compound (e.g., a metal corrosion inhibitor) or a surfactant included in the etching solution is reacted with isopropyl alcohol.

An additional cleaning process may be necessary for removing the impurities before forming a dielectric layer on the lower electrode. It may be difficult to remove the impurities from the lower electrode by the additional cleaning process.

In a manufacturing process of the lower electrode having the cylindrical shape, a method for removing the organic compound, which remains after the etching process, may still be necessary.

### SUMMARY OF THE INVENTION

Example embodiments of the present invention relate to a method of cleaning a semiconductor device and a method of manufacturing a semiconductor device using the same. Other example embodiments of the present invention relate to a method of cleaning a semiconductor device by removing a residual organic compound and a method of manufacturing a semiconductor device using the same.

Example embodiments of the present invention provide a method of cleaning a semiconductor device using an ozone solution. Example embodiments of the present invention provide a method of manufacturing a semiconductor device using an ozone solution.

According to example embodiments of the present invention, there is provided a method of cleaning a semiconductor device. In the method, an oxide layer having an opening may be formed on a substrate. A conductive layer may be formed in the opening. The oxide layer may be removed using an etching solution including an organic compound. An ozone solution may be used to remove a residual organic compound that adheres to the substrate and the conductive layer.

In example embodiments of the present invention, the etching solution may include a low ammonium liquid (LAL) solution including the organic compound, ammonium fluoride, hydrogen fluoride and/or water. The organic compound may include a metal corrosion inhibitor and/or a surfactant. The ozone solution may include about 5 ppm to about 100 ppm of ozone. In other example embodiments of the present invention, the ozone solution may also include about 0.001 percent by weight (% wt) to about 0.02 percent by weight (% wt) of hydrogen fluoride.

In example embodiments of the present invention, a first rinsing process using deionized water may be performed, after removing the oxide layer. According to example embodiments of the present invention, removal of the oxide layer and the residual organic compound may be performed in-situ. In yet other example embodiments of the present invention, a second rinsing process using deionized water and a dry process using an isopropyl alcohol vapor may be performed, after removing the residual organic compound.

According to example embodiments of the present invention, there is provided a method of manufacturing a semiconductor device. In the method, a mold layer pattern including an opening may be formed on a substrate. A conductive layer may be conformably formed, or form-fitted, on the mold layer pattern in the opening. A buffer layer may be formed on the conductive layer to fill the opening. The buffer layer and the conductive layer pattern may be partially removed until the mold layer is exposed to form a lower electrode and a buffer layer pattern in the lower electrode. The mold layer pattern may be removed using an etching solution including an organic compound. A residual organic compound that adheres to the lower electrode may be removed using an ozone solution.

According to example embodiments of the present invention, the organic compound may include a metal corrosion inhibitor and/or a surfactant. The ozone solution may include about 5 ppm to about 100 ppm of ozone. The ozone solution may also include about 0.001% wt to about 0.02% wt of hydrogen fluoride.

After removing the residue, a rinsing process using deionized water may be performed, followed by a drying process using an isopropyl alcohol vapor.

In example embodiments of the present invention, the buffer layer may be formed using a material having an etching selectivity relative to an etching selectivity the mold layer pattern. The buffer layer may be formed using a photoresist. The lower electrode may be a material selected from the group including tungsten, titanium, tungsten nitride and titanium nitride.

In example embodiments of the present invention, the etching solution may be a LAL solution including the organic compound, ammonium fluoride, hydrogen fluoride and/or water.

According to yet other example embodiments of the present invention, the buffer layer pattern may be removed, after removing the residual organic compound. A dielectric layer may be formed on the lower electrode. An upper electrode may be formed on the dielectric layer.

According to example embodiments of the present invention, an organic compound, which is formed from a reaction between impurities and isopropyl alcohol used in drying process, may not be formed on a lower electrode. An increase in the electrical resistance of a capacitor may be prevented or retarded. An additional cleaning process for removing the organic compound may not be necessary due to an increase in a throughput or efficiency of a manufacturing process of a semiconductor device.

### BRIEF DESCRIPTION OF THE DRAWINGS

Example embodiments of the present invention will be more clearly understood from the following detailed description taken in conjunction with the accompany drawings. FIGS. 1-13 represent non-limiting, example embodiments of the present invention as described herein.

FIGS. 1 to 5 are diagrams illustrating cross sectional views of a method of cleaning a semiconductor device in accordance with example embodiments of the present invention; and

FIGS. 6 to 13 are diagrams illustrating cross sectional views of a method of manufacturing a semiconductor device in accordance with example embodiments of the present invention.

### DETAILED DESCRIPTION OF EXAMPLE EMBODIMENTS

Various example embodiments of the present invention will now be described more fully with reference to the accompanying drawings in which some example embodiments of the invention are shown. In the drawings, the thicknesses of layers and regions may be exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items. It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Also, the use of the words “compound,” “compounds,” or “compound(s),” refer to either a single compound or to a plurality of compounds. These words are used to denote one or more compounds but may also just indicate a single compound.

Example embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved. Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

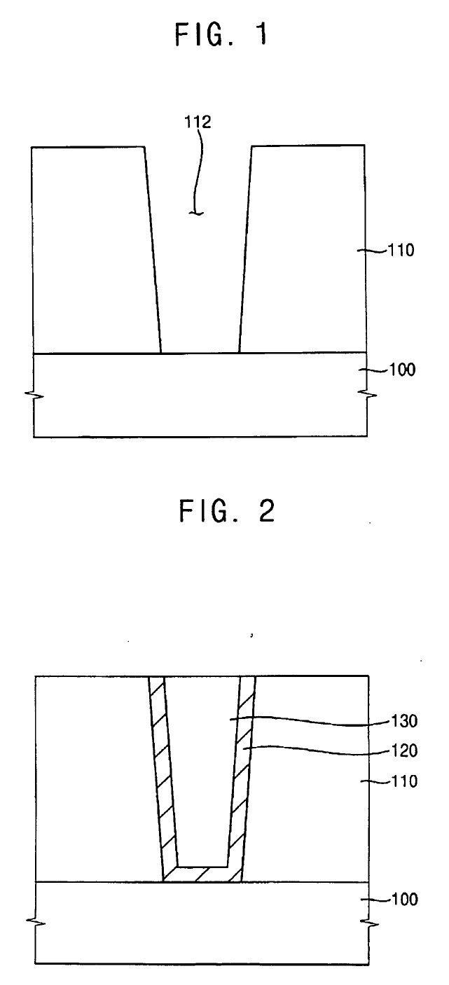

FIGS. 1 to 5 are diagrams illustrating cross sectional views of a method of cleaning a semiconductor device in accordance with example embodiments of the present invention.

Referring to FIG. 1, an oxide layer pattern 110 may be formed on a substrate 100. The oxide layer pattern 110 may include an opening 112 that partially exposes the substrate 100.

In example embodiments of the present invention, an oxide layer may be formed on the substrate 100. The substrate 100 may include a lower structure (e.g., a contact, a pad, a plug, a gate structure, a contact region, a transistor, an insulation layer, an insulating interlayer or similar structures). The oxide layer may be formed using an oxide (e.g., boro phosphor silicate glass (BPSG), phosphor silicate glass (PSG), boro silicate glass (BSG), undoped silicate glass (USG), spin on glass (SOG), plasma enhanced-tetraethyl orthosilicate (PE-TEOS), high density plasma-chemical vapor deposition (HDP-CVD) oxide or similar compound). The oxide layer may be formed by a chemical vapor deposition (CVD) process, a plasma enhanced-CVD (PE-CVD) process, an atomic layer deposition (ALD) process, a high density plasma-CVD (HDP-CVD) process or similar method. The oxide layer may be used as an insulating interlayer or a mold layer for forming a lower electrode of a capacitor.

When the oxide layer is used as the mold layer, the oxide layer may be formed having a thickness of about 5,000 Å to about 20,000 Å measured from an upper face of the substrate 100. The thickness of the oxide layer may be adjusted according to a height of the capacitor.

A mask pattern (not shown) may be formed on the oxide layer. The mask pattern may be formed using a material having an etching selectivity relative to that of the oxide layer. For example, when the oxide layer is formed using silicon oxide, the mask pattern may be formed using a nitride (e.g., silicon nitride). The mask pattern selectively exposes the oxide layer. In example embodiments of the present invention, a photoresist pattern may be formed on the mask pattern.

An exposed portion of the oxide layer may be anisotropically etched using the mask pattern as an etching mask to form the opening 112. The opening 112 exposes the lower structure below the oxide layer. The oxide layer may be patterned to form the oxide layer pattern 110 on the substrate 100.

A lower electrode of a capacitor, which may be electrically connected to a contact pad of the substrate 100, may be formed in the opening 112. According to example embodiments of the present invention, an etch stop layer (not shown) may be formed on the substrate 100 before forming the oxide layer on the substrate 100. The etch stop layer may prevent, or reduce, damage to the substrate 100 in an etching process for forming the opening 112.

Referring to FIG. 2, a conductive layer may be conformably formed, or form-fitted, on a sidewall and a surface of the oxide layer pattern 110. The conductive layer may be conformably formed, or form-fitted, on the substrate 100 exposed by the opening 112.

In yet other example embodiments of the present invention, the conductive layer may be formed in a single layer structure using polysilicon, a metal, a conductive metal nitride, etc. In other example embodiments of the present invention, the conductive layer may be formed in a multi-layer structure using polysilicon, a metal, a conductive metal nitride, etc. For example, the conductive layer may be formed using titanium (Ti), tantalum (Ta), tungsten (W), titanium nitride (TiN), tantalum nitride (TaN), tungsten nitride (WN) or a combination thereof. The conductive layer may be formed by a sputtering process, a CVD process, a pulsed laser deposition (PLD) process, an ALD process or similar process.

A buffer layer may be formed on the conductive layer to fill the opening 112. In example embodiments of the present invention, the buffer layer may be formed using a photoresist. In other example embodiments of the present invention, the buffer layer may be formed using an oxide (e.g., BPSG, PSG, BSG, USG, SOG, PE-TEOS, HDP-CVD oxide or similar compound).

The buffer layer and the conductive layer may be partially removed by a chemical mechanical polishing (CMP) process, an etch back process or a combination process thereof. The buffer layer and the conductive layer may be partially removed until the oxide layer pattern 110 is exposed. A conductive layer pattern 120 having a cylindrical shape may be formed in the opening 112. A buffer layer pattern 130 may be formed on the conductive layer pattern 120 to fill the opening 112.

The buffer layer pattern 130 may prevent, or reduce, damage to the conductive layer pattern 120 during removal of the oxide layer pattern 110 and the conductive layer pattern 120 in order to form a lower electrode.

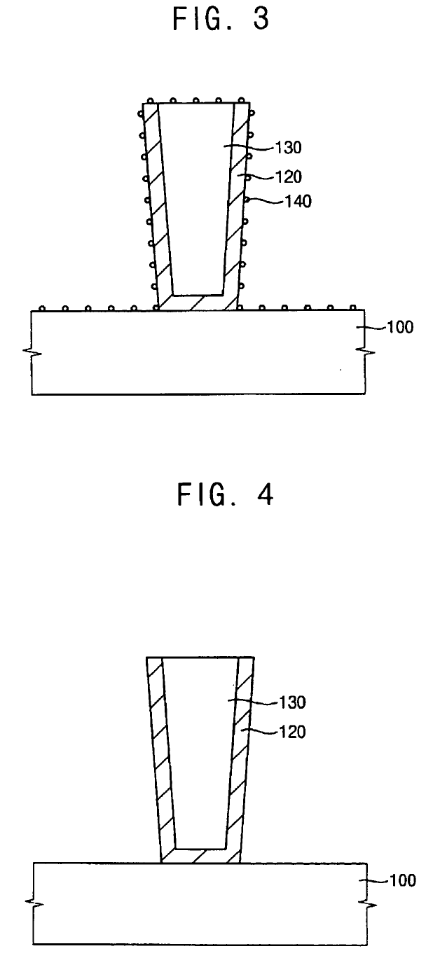

Referring to FIG. 3, the oxide layer pattern 110 may be removed from the substrate 100. The oxide layer pattern 110 may be removed using an etching solution including an organic compound. An outer wall of the conductive layer pattern 120 may be exposed after removing the oxide layer pattern 110 from the substrate 100.

The etching solution used for removing the oxide layer pattern 110 may include the organic compound. Examples of the organic compound may include a metal corrosion inhibitor, a surfactant, etc. The surfactant may include a cationic surfactant or an anionic surfactant.

In example embodiments of the present invention, the etching solution may include water, a hydrogen fluoride solution, an ammonium fluoride solution and/or a surfactant. In other example embodiments of the present invention, the etching solution may include water, a hydrogen fluoride solution, an ammonium fluoride solution and/or a metal corrosion inhibitor.

In an etching process for etching the oxide layer pattern 110 using the etching solution, the conductive layer pattern 120 may have a lower etching rate relative to that of the oxide layer pattern 110. The oxide layer pattern 110 may be more effectively removed from the substrate 100 using the etching solution without etching damage to the conductive layer pattern 120.

In example embodiments of the present invention, a first rinsing process using deionized water may be performed on the substrate 100, after removing the oxide layer pattern 110. The first rinsing process may remove any etching solution remaining on the substrate 100. A residual oxide may also be removed from the substrate 100 by the first rinsing process. The first rinsing process may be performed for about three minutes to about five minutes.

After the etching process and the first rinsing process, a residue 140 may remain on the substrate 100 and the conductive layer pattern 120. The residue 140 may include a metal compound, a first organic compound, a second organic compound, an oxide compound, etc.

The metal compound and the first organic compound may form during a CMP process for forming the conductive layer pattern 120 and the buffer layer pattern 130. A substantial amount of, or entire, metal compound and first organic compound may be removed in the etching process of the oxide layer pattern 110. The metal compound may also be removed in the first rinsing process.

The oxide compound may form during the etching process of the oxide layer pattern 110. The second organic compound may form due to a portion of the surfactant or the metal corrosion inhibitor included in the etching solution remaining after the first rinsing process. The second organic compound may adhere to the substrate 100 and the conductive layer pattern 120.

A third organic compound may form due to a reaction between the second organic compound and isopropyl alcohol in a subsequent drying process. In subsequent cleaning processes, the third organic compound may be more difficult to remove from the substrate 100 and/or the conductive layer pattern 120. Defects in the semiconductor device may occur due to the third organic compound.

Referring to FIG. 4, the residue 140 may be removed from the substrate 100 by a cleaning process. The cleaning process may be performed using an ozone solution. The cleaning process may remove the residue 140 adhering to the substrate 100 and/or the conductive layer pattern 120 without damage to the substrate 100 or the conductive layer pattern 120.

In example embodiments of the present invention, the ozone solution may include deionized water and ozone. In yet other example embodiments of the present invention, the ozone solution may include deionized water, ozone and/or hydrogen fluoride.

The ozone solution may include about 5 ppm to about 100 ppm of ozone. The ozone solution may be prepared by dissolving ozone in deionized water.

When the ozone solution includes less than about 5 ppm of ozone, a cleaning ability of the ozone solution, to remove the residue 140 and/or the second organic compound that may remain on the substrate 100 and the conductive layer pattern 120, may be reduced.

When the ozone solution includes more than about 100 ppm of ozone, the residue 140 and the second organic compound may be more effectively removed. When the ozone solution includes more than about 100 ppm of ozone, the conductive layer pattern 120 may be oxidized. It is desirable that the ozone solution may include about 5 ppm to about 100 ppm by weight of ozone. The ozone solution may include about 10 ppm to about 70 ppm by weight of ozone.

In example embodiments of the present invention, the ozone solution may include about 0.001 percent by weight (% wt) to about 0.02 percent by weight (% wt) of hydrogen fluoride (HF). The ozone solution may also include about 5 ppm by weight to about 100 ppm by weight of ozone.

The ozone solution may include about 0.001% wt to about 0.02% wt of hydrogen fluoride. The ozone solution may include about 0.005 to about 0.02% wt of hydrogen fluoride. Hydrogen fluoride used for manufacturing the ozone solution may have a concentration of about 40 percent to about 60 percent. The hydrogen fluoride may have a concentration of about 50 percent.

The ozone solution may more effectively remove the residue 140 without excessively etching the conductive layer pattern 120 including a metal or a metal nitride.

In example embodiments of the present invention, a second rinsing process may be performed on the substrate 100 using pure water to remove a residual ozone solution from the substrate 100. The etching residue and/or impurities, which may remain on the substrate 100 after the cleaning process using the ozone solution, may be removed by the second rinsing process. In example embodiments of the present invention, a second drying process may be performed on the substrate 100. The second drying process may be performed using a vapor including isopropyl alcohol.

Because the second organic compound may be removed from the substrate 100, impurities resulting from a reaction of the second organic compound with isopropyl alcohol may not form on the substrate 100.

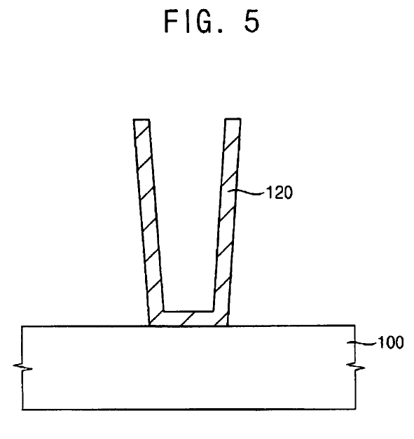

Referring to FIG. 5, the buffer layer pattern 130 may be removed to expose the conductive layer pattern 120. The buffer layer pattern 130 may be removed by a wet etching process or a dry etching process. The conductive layer pattern 120 may be electrically connected to the substrate 100. The conductive layer pattern 120 may be used as a metal wiring or a lower electrode.

In example embodiments of the present invention, when the buffer layer pattern 130 includes photoresist, the buffer layer pattern 130 may be removed by an ashing process using plasma (e.g., oxygen plasma) and/or a stripping process. In example embodiments of the present invention, a third rinsing process using deionized water may be performed on the substrate 100 to remove any remaining stripping solution.

An etching residual and a residual photoresist may be removed from the substrate 100 by the third rinsing process. A drying process may be performed on the substrate 100 to remove water that may remain on the substrate 100.

When the buffer layer pattern 130 includes oxide, the buffer layer pattern 130 may be removed while the oxide layer pattern 110 is being removed using the etching solution according to the present invention.

A cleaning process according to example embodiments of the present invention may be performed in various manufacturing processes of semiconductor devices including conductive structures. For example, the cleaning process may be more effectively performed in a manufacturing process of a lower electrode of a capacitor.

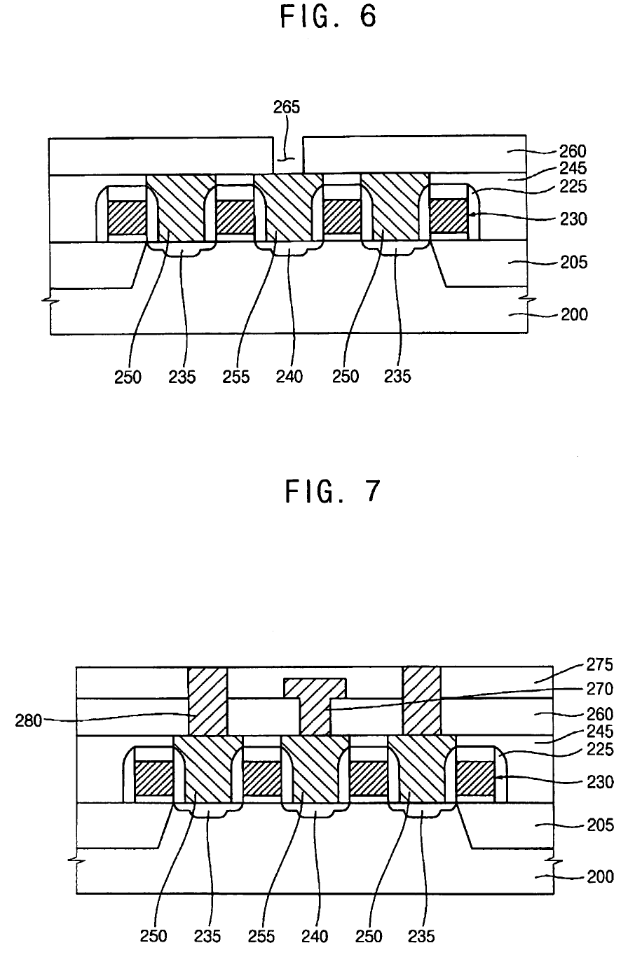

FIGS. 6 to 13 are diagrams illustrating cross sectional views of a method of manufacturing a semiconductor device in accordance with example embodiments of the present invention.

Referring to FIG. 6, an isolation layer 205 may be formed on a substrate 200 by an isolation process (e.g., a shallow trench isolation (STI) process) to define an active region and/or a field region on the substrate 200.

A gate insulation layer may be formed on the substrate 200 including the isolation layer 205 thereon. The gate insulation layer may be formed by a thermal oxidation process, a CVD process, an ALD process or similar process. The gate insulation layer may be formed using silicon oxide or a material having a higher dielectric constant than that of silicon oxide. Examples of the material having a higher dielectric constant may include a metal oxide. The metal oxide may include hafnium oxide (HfO₂), zirconium oxide (ZrO₂), tantalum oxide (Ta₂O₅), yttrium oxide (Y₂O₃), niobium oxide (Nb₂O₅), aluminum oxide (Al₂O₃), titanium oxide (TiO₂), cerium oxide (CeO₂), indium oxide (In₂O₃), ruthenium oxide (RuO₂), magnesium oxide (MgO), strontium oxide (SrO), boron oxide (B₂O₃), tin oxide (SnO₂), lead oxide (PbO, PbO₂, Pb₃O₄), vanadium oxide (V₂O₃), lanthanum oxide (La₂O₃), praseodymium oxide (Pr₂O₃), antimony oxide (Sb₂O₃, Sb₂O₅), calcium oxide (CaO) or a combination thereof.

A first conductive layer and a gate mask may be formed on the gate insulation layer. The first conductive layer may be formed using polysilicon doped with impurities. The first conductive layer may be patterned to form a gate electrode. The first conductive layer may be formed in a polycide structure. The polycide structure may include a polysilicon layer and a metal silicide layer formed on the polysilicon layer.

The gate mask may be formed using a material having an etching selectivity relative to that of a first insulating interlayer 245, formed in a subsequent process. For example, when the first insulating interlayer 245 is formed using an oxide (e.g., silicon oxide), the gate mask may be formed using a nitride (e.g., silicon nitride).

The first conductive layer and the gate insulation layer may be successively patterned using the gate mask as an etching mask. A gate structure 230 including a gate insulation layer pattern, a gate electrode and the gate mask may be formed on the substrate 200.

The insulation layer may be formed on the substrate 100 including the gate structure 230 thereon. The insulation layer may be formed using a nitride (e.g., silicon nitride). The insulation layer may be anisotropically etched to form a gate spacer 225 on both sidewalls of the gate structure 230.

Impurities may be implanted into portions of the substrate 200 adjacent to the gate structure 230 by an ion implantation process using the gate structure 230 as an ion implantation mask. A thermal treatment process may be performed on the substrate 200 to form a first contact region 235 and a second contact region 240 that may correspond to source/drain regions.

The first contact region 235 and the second contact region 240 may be divided into a capacitor contact pad and a bit line contact pad, respectively. For example, the first contact region 235 may correspond to a capacitor contact region, which may contact a first pad 250. The second contact region 240 may correspond to a bit line contact region, which may contact a second pad 255. A transistor including the gate structure 230, the gate spacer 225, the first contact region 235 and/or the second contact region 240 may be formed on the substrate 200.

A first insulating interlayer 245 may be formed on the substrate 200 to cover the gate structure 230. The first insulating interlayer 245 may be formed using an oxide (e.g., BPSG, PSG, SOG, USG, PE-TEOS, HDP-CVD oxide or similar compound). The first insulating interlayer 245 may be formed by a deposition process (e.g., a CVD process, a PE-CVD process, an HDP-CVD process, an ALD process or similar process).

The first insulating layer 245 may be partially removed by a CMP process, an etch back process or a combination process thereof. In example embodiments of the present invention, the first insulating interlayer 245 may have a desired height from the gate mask. In other example embodiments of the present invention, the first insulating interlayer 245 may be partially removed until the gate mask is exposed such that the first insulating interlayer 245 may have a height substantially the same as that of the gate structure 230.

A first photoresist pattern (not shown) may be formed on the first insulating interlayer 245. The first insulating interlayer 245 may be partially etched using the first photoresist pattern as an etching mask to form first contact holes. The first contact holes may expose the first contact region 235 and the second contact region 240 through the first insulating interlayer 245. The first contact holes may be self-aligned with respect to the gate structure 230 and expose the first contact region 235 and the second contact region 240.

A portion of the first contact holes may expose the first contact region 235 and another portion of the first contact holes may expose the second contact region 240.

The first photoresist pattern may be removed from the first insulating interlayer 245 by an ashing process and/or a stripping process. A second conductive layer may be formed on the first insulating interlayer 245 to fill the first contact holes. The second conductive layer may be formed using polysilicon doped with impurities, a metal, a conductive metal nitride, etc.

The second conductive layer may be partially removed by a CMP process, an etch back process or a combination thereof until the first insulating interlayer 245 is exposed. A first pad 250 and a second pad 255 may be formed in the first contact holes as self-aligned contact (SAC) pads. The first pad 250 may be formed on the first contact region 235 and the second pad 255 may be formed on the second contact region 240. The first pad 250 may electrically contact the first contact region 235. The second pad 255 may electrically contact the second contact region 240.

A second insulating interlayer 260 may be formed on the first insulating interlayer 245 including the first pad 250 and the second pad 255. The second insulating interlayer 260 may electrically insulate the first pad 250 from the bit line, formed in a subsequent process. The second insulating interlayer 260 may be formed using an oxide (e.g., BPSG, PSG, SOG, USG, PE-TEOS, HDP-CVD oxide or similar compound). The second insulating interlayer 260 may be formed by a deposition process (e.g., a CVD process, a PE-CVD process, an HDP-CVD process, an ALD process or similar process).

In example embodiments of the present invention, the second insulating interlayer 260 may be formed using a material substantially the same as that of the first insulating interlayer 245. In other example embodiments of the present invention, the second insulating interlayer 260 may be formed using a material substantially different from that of the first insulating interlayer 245.

The second insulating layer 260 may be partially removed by a CMP process, an etch back process or a combination thereof. A second photoresist pattern (not shown) may be formed on the second insulating interlayer 260. The second insulating interlayer 260 may be partially etched using the second photoresist pattern as an etching mask. A second contact hole 265, exposing the second pad 255, may be formed through the second insulating interlayer 260. The second contact hole 265 may be used to form a bit line 270 (see FIG. 7), electrically connected to the second pad 255.

Referring to FIG. 7, the second photoresist pattern may be removed from the second insulating interlayer 260 by an ashing process and/or a stripping process. A third conductive layer may be formed on the second insulating interlayer 260 to fill the second contact hole 265.

A third photoresist pattern (not shown) may be formed on the third conductive layer. The third conductive layer may be etched using the third photoresist pattern as an etching mask to form the bit line 270. The bit line 270 may be electrically connected to the second pad 255. In example embodiments of the present invention, the bit line 270 may have a multi-layer structure that includes a first layer including a metal/metal compound and a second layer including a metal. For example, the bit line. 270 may have the first layer including titanium/titanium nitride (Ti/TiN) and the second layer including tungsten (W).

The third photoresist pattern may be removed from the bit line 270 by an ashing process and/or a stripping process. A third insulating interlayer 275 may be formed on the second insulating interlayer 260 to cover the bit line 270. The third insulating interlayer 275 may be formed using an oxide (e.g., BPSG, PSG, SOG, USG, PE-TEOS, HDP-CVD oxide or similar compound). The third insulating interlayer 275 may be formed using a similar material as that of the second insulating interlayer 260. Alternatively, the third insulating interlayer 275 may be formed using a different material from that of the second insulating interlayer 260.

The third insulating interlayer 275 may be partially removed by a CMP process, an etch back process or a combination thereof to planarize the third insulating interlayer 275. In example embodiments of the present invention, additional insulating interlayers including nitride may be formed on the second insulating interlayer 260 and the bit line 270. The third insulating interlayer 275 may be formed on the additional insulating interlayers. The additional insulating interlayers may prevent, or reduce, a void or a seam from forming in the third insulating interlayer 275.

A fourth photoresist pattern (not shown) may be formed on the third insulating interlayer 275. The third insulating interlayer 275 and the second insulating interlayer 260 may be partially etched using the fourth photoresist pattern as an etching mask. A third contact hole exposing the first pad 250 may be formed. For example, the third contact hole may correspond to capacitor contact holes. The fourth photoresist pattern may be removed from the third insulating interlayer 275 by an ashing process and/or a stripping process.

A fourth conductive layer may be formed on the third insulating interlayer 275 to fill the third contact hole. The fourth conductive layer may be partially removed by a CMP process, an etch back process or a combination thereof, forming a third pad 280 in the third contact hole. The third pad 280 may be formed using polysilicon doped with impurities, a metal, a conductive metal nitride, etc. The third pad 280 may electrically connect the first pad 250 with a lower electrode to be formed in a subsequent process.

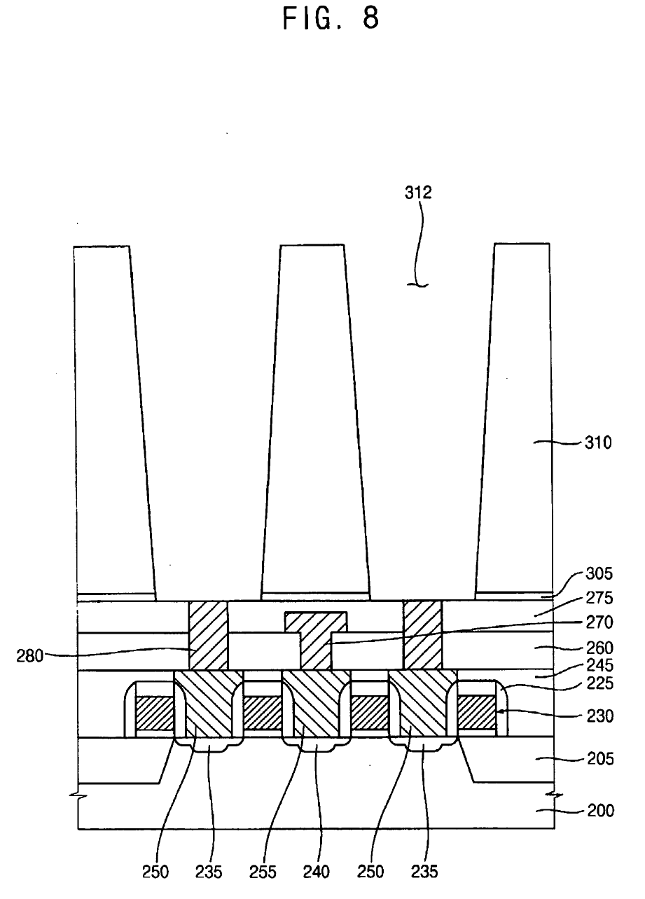

FIG. 8 is a diagram illustrating a cross sectional view of a process of forming an etch stop layer and a mold layer pattern including an opening according to example embodiments of the present invention.

Referring to FIG. 8, an etch stop layer 305 may be formed on the third insulating interlayer 275 and the third pad 280. The etch stop layer 305 may prevent or reduce etching damage to the third pad 280 in an etching process of a mold layer for forming an opening 312. The etch stop layer 305 may have a thickness of about 10 Å to about 200 Å. The etch stop layer 305 may be formed using a nitride or a metal oxide having an etching selectivity relative to that of a buffer layer, formed in a subsequent process.

A mold layer may be formed on the etch stop layer 305. The mold layer may be formed using an oxide (e.g., BPSG, PSG, USG, SOG, PE-TEOS, HDP-CVD oxide or similar compound). The mold layer may have a thickness of about 10,000 Å to about 20,000 Å. The thickness of the mold layer may be controlled according to a capacitance necessary for a capacitor.

A mask pattern (not shown) may be formed on the mold layer. The mold layer may be anisotropically etched using the mask pattern as an etching mask. The etch stop layer 305 may be successively etched using the mask pattern as an etching mask. An opening 312, exposing the third pad 280, may be formed through the mold layer and the etch stop layer 305. The mold layer may be formed into a mold layer pattern 310 having the opening 312.

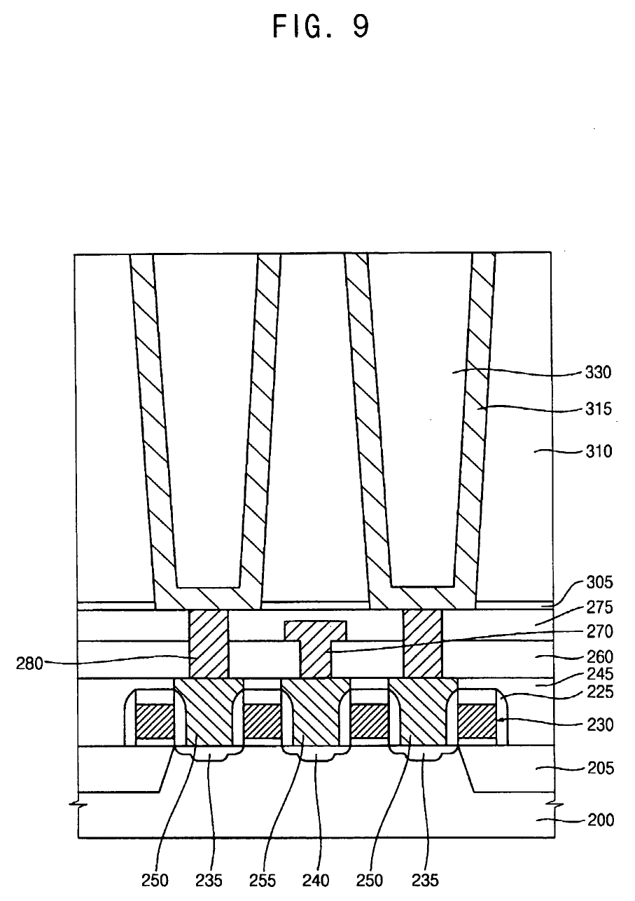

FIG. 9 is a diagram illustrating a cross sectional view of a process of forming a lower electrode and a buffer layer pattern according to example embodiments of the present invention.

Referring to FIG. 9, a lower electrode layer 315 may be conformably formed, or form-fitted, in the opening 312. The lower electrode layer 315 may be formed on the mask pattern. The lower electrode layer 315 may be formed using a metal (e.g., tungsten, titanium or the like) or a conductive metal nitride (e.g., tungsten nitride, titanium nitride or the like). The lower electrode layer 315 may be formed having a thickness of about 300 Å to about 500 Å.

A buffer layer may be formed on the lower electrode layer 315 to fill the opening 312. In example embodiments of the present invention, the buffer layer may be formed using an oxide. In example embodiments of the present invention, the buffer layer may be formed using a photoresist. When the buffer layer is formed using the photoresist, a photoresist composition may be coated on the substrate 200. A first baking process may be performed in order to form a preliminary photoresist film having an enhanced or increased adhesion characteristic. An exposure process and a second baking process may be performed on the preliminary photoresist film to form a photoresist film (e.g., the buffer layer).

The buffer layer, the lower electrode layer 315 and the mask pattern may be partially removed until the mold layer pattern 310 is exposed. The lower electrode layer 315 may be formed having a cylindrical shape. A buffer layer pattern 330 may be formed in the opening 312.

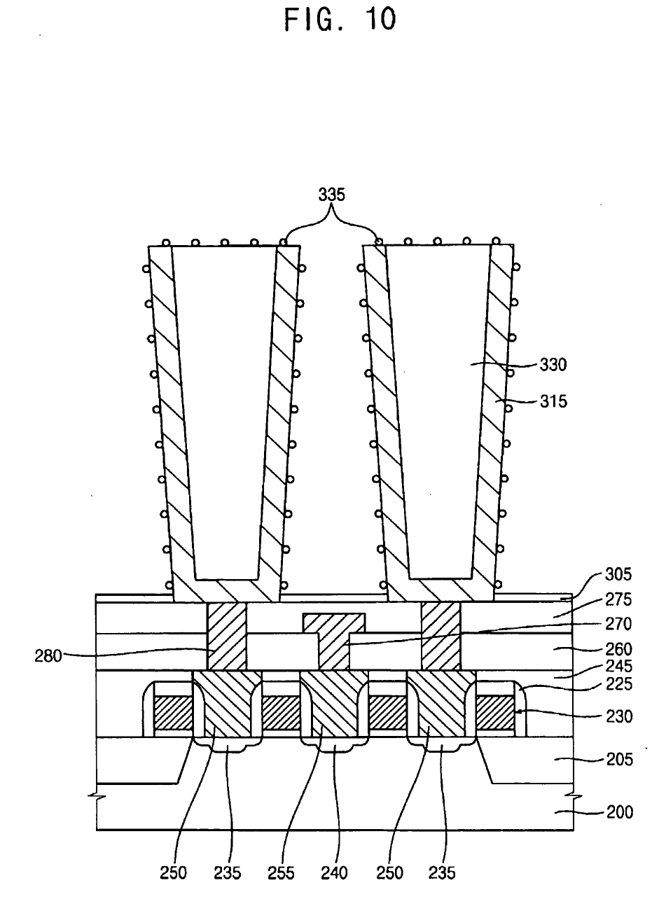

Referring to FIG. 10, the mold layer pattern 310 may be removed from the substrate 200 using an etching solution including an organic compound. When the mold layer pattern 310 is removed, an outside wall of the lower electrode layer 315 may be exposed and the lower electrode layer 315 may be separated into a unit cell.

The etching solution for removing the mold layer pattern 310 may include the organic compound. Examples of the organic compound may include a metal corrosion inhibitor, a surfactant, etc. The surfactant may include a cationic surfactant or an anionic surfactant.

In example embodiments of the present invention, the etching solution may include water, a hydrogen fluoride solution, an ammonium fluoride solution and/or a surfactant. When the etching solution having the above-mentioned composition is used to remove the mold layer pattern 310, the lower electrode layer 315 may have a lower etching rate relative to that of the mold layer pattern 310. The mold layer pattern 310 may be more effectively removed using the etching solution without etched damage to the lower electrode layer 315.

After performing the etching process using the etching solution, impurities (e.g., a metal compound, a first organic compound, an oxide compound and/or a second organic compound) may remain on the lower electrode layer 315. The second organic compound 335, remaining on the lower electrode layer 315, may cause problems.

The impurities may be removed in a rinsing process. The second organic compound 335 may not be removed in the rinsing process. A third organic compound may form due to a reaction between the second organic compound 335 and isopropyl alcohol in a subsequent drying process. The third organic compound may be more difficult to remove from the lower electrode layer 315. Defects in the semiconductor device may occur due to the third organic compound.

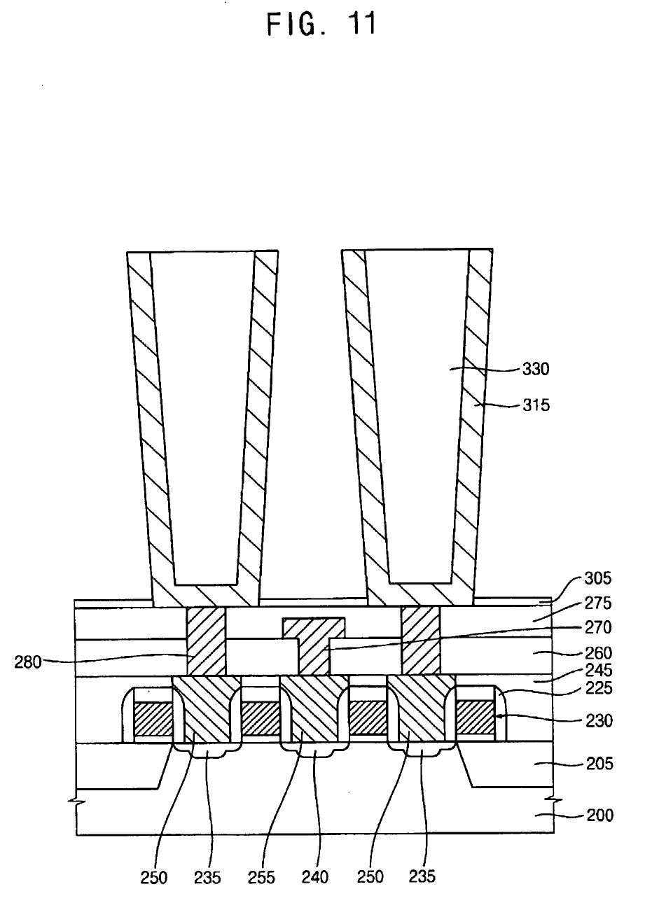

Referring to FIG. 11, a cleaning process using an ozone solution may be performed on the substrate 200 to remove the second organic compound 335. The cleaning process may remove the second organic compound 335 adhering to the lower electrode layer 315 without damage to the lower electrode layer 315.

In example embodiments of the present invention, the ozone solution may include deionized water and ozone. In other example embodiments of the present invention, the ozone solution may include deionized water, ozone and/or hydrogen fluoride. The ozone solution may be substantially the same as the ozone solution described with reference to FIGS. 1 to 5.

In example embodiments of the present invention, a second rinsing process and a drying process may be performed on the substrate 200. The second rinsing process may be performed on the substrate 200 to remove a residual ozone solution and/or etching residual. The drying process may be performed by vaporizing isopropyl alcohol.

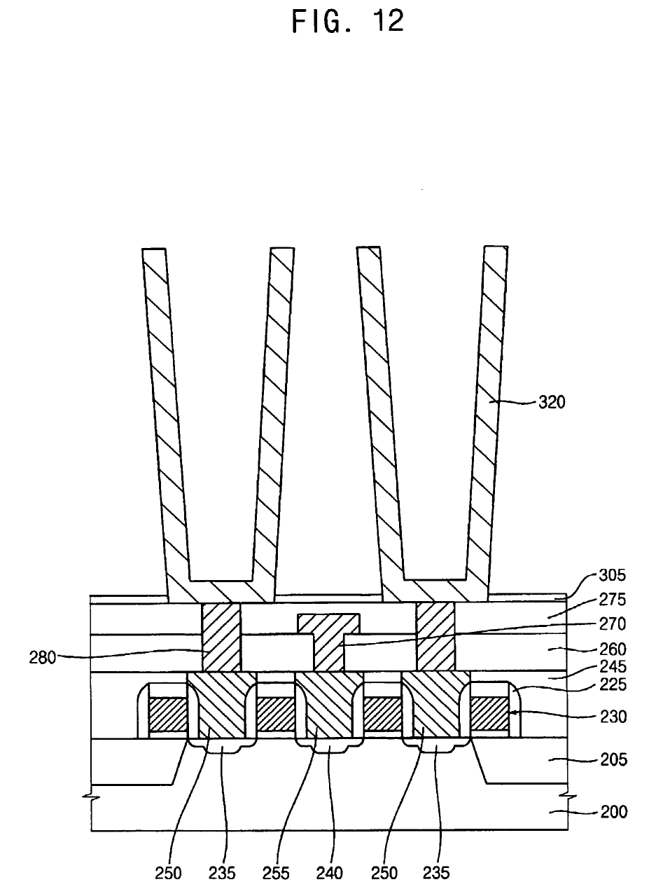

Referring to FIG. 12, the buffer layer pattern 330 in the lower electrode layer 315 may be removed. When the buffer layer pattern 330 is a photoresist pattern formed using a photoresist, the buffer layer pattern 330 may be removed from the lower electrode layer 315 by an ashing process and/or a stripping process. A lower electrode 320 may be formed on the substrate 200. The lower electrode 320 may have a cylindrical shape. The lower electrode 320 may be electrically connected to the third contact pad 280. The lower electrode 320 may have a higher aspect ratio. The lower electrode 320 may be arranged adjacently on a respective cell area.

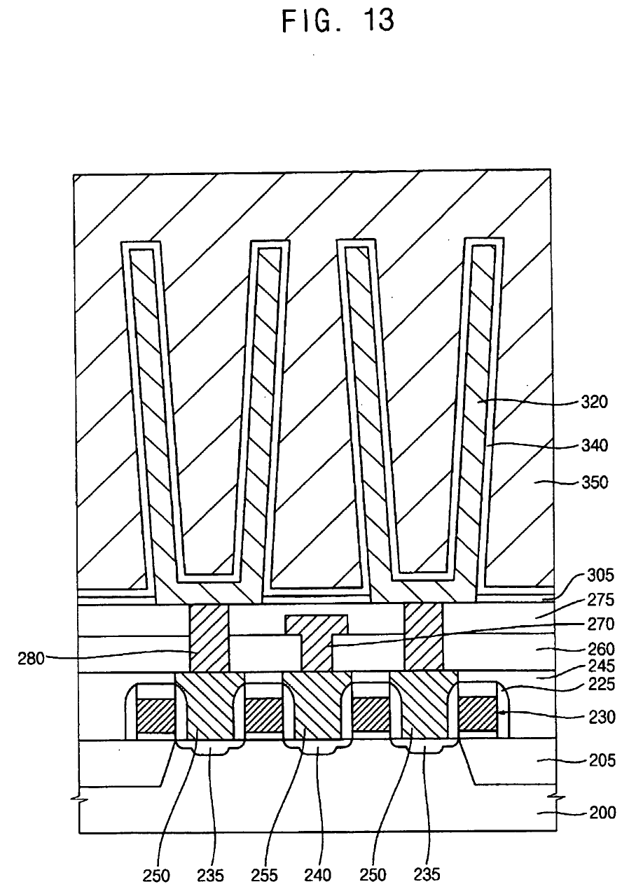

FIG. 13 is a diagram illustrating a cross sectional view of a process of forming a dielectric layer and an upper electrode according to example embodiments of the present invention.

Referring to FIG. 13, a dielectric layer 340 may be formed on the lower electrode 320, after forming the lower electrode 320.

The dielectric layer 340 may be formed using an oxide/nitride, an oxide/nitride/oxide, a metal oxide, etc. In example embodiments of the present invention, the dielectric layer 340 may be formed using a metal oxide that has a thinner equivalent oxide thickness (EOT) and/or a higher dielectric constant. The dielectric layer 340 may be formed by an ALD process.

When the dielectric layer 340 is formed by the ALD process, a unit process including providing a reactant, purging the reactant, providing an oxidant and/or purging the oxidant may be repeated at least once. The dielectric layer 340 including the metal oxide may be formed on the lower electrode 320. The reactant may include a metal precursor. Examples of the metal precursor may include a hafnium precursor (e.g., tetrakis ethyl methyl amino hafnium (TEMAH) (Hf[NC₂H₅CH₃]₄), hafnium butyl oxide (Hf(OtBu)₄) or the like) and/or an aluminum precursor (e.g., trimethyl aluminum (Al(CH₃)₃) or the like). Examples of the oxidant may include ozone (O₃), oxygen (O₂), water (H₂O), an oxygen plasma, a remote oxygen plasma or the like.

For example, when the dielectric layer 340 includes a hafnium oxide, a unit process including providing TEMAH, purging TEMAH, providing ozone and/or purging ozone may be repeated at least once.

An upper electrode 350 may be formed on the dielectric layer 340. The upper electrode 350 may be formed using polysilicon doped with impurities, a metal, a metal nitride, etc. As an integration degree of the semiconductor device becomes higher, it may be desirous to use a metal nitride to form the upper electrode 350. For example, the upper electrode 350 may be formed by a CVD process using titanium nitride. When the upper electrode 350 is formed by the CVD process, the CVD process may be performed at a temperature of less than about 550° C. and using a reactant gas (e.g., a titanium chloride (TiCl₄) gas, an ammonium (NH₃) gas or the like).

A capacitor including the lower electrode 320, the dielectric layer 340 and the upper electrode 350 may be formed on the substrate 200. The capacitor may include the lower electrode 320 having a cylindrical shape such that the capacitor may have a more sufficient capacitance. When the lower electrode 320 is formed using an etching solution including an organic compound, a residual organic compound on the lower electrode 320 may be more effectively removed by the ozone solution according to example embodiments of the present invention. The capacitor having increased characteristics may be formed.

Evaluation of a Remaining Organic Compound

In order to evaluate whether an organic compound remains during a removal process of an oxide layer using a low ammonium liquid (LAL) etching solution, a titanium nitride layer having a thickness of about 600 Å and a silicon oxide layer having a thickness of about 1,000 Å were successively formed on a substrate. The silicon oxide layer was removed from the substrate using a LAL etching solution including a surfactant. The titanium nitride layer was exposed. Water was sprayed on the titanium nitride layer to form a first waterdrop on the titanium nitride layer. A first contact angle of the first waterdrop on the titanium nitride layer was measured. The first contact angle was in a range of about 60° to about 70°. The first contact angle in the range of about 60° to about 70° may mean that a surface of the titanium nitride layer is hydrophobic. Impurities (e.g., the surfactant) may remain on the surface of the titanium nitride layer.

Evaluation of a Removing Ability of an Ozone Solution for an Organic Compound

The substrate prepared by the above-described process was cleaned using an ozone solution including about 50 ppm of ozone for about three minutes. A rinsing process and a drying process were performed to remove a residual ozone solution. Water was sprayed on the titanium nitride layer to form a second waterdrop on the titanium nitride layer. A second contact angle of the second waterdrop on the titanium nitride layer was measured. The second contact angle was in a range of about 5° to about 10°. The second contact angle, in the range less than about 10°, may demonstrate that the surface of the titanium nitride layer is hydrophilic. The impurities (e.g., the surfactant) may be removed from the surface of the titanium nitride layer by the ozone solution.

According to example embodiments of the present invention, a cleaning process using an ozone solution may function to remove a residue from a substrate in the formation of a lower electrode.

An organic compound, which may form due to a reaction between the residue and isopropyl alcohol used in a drying process, may not form on the lower electrode. The organic compound may not form after the drying process such that an electrical resistance in a capacitor may not increase. As such, a capacitor having a desired capacitance may be formed.

Subsequent cleaning processes for removing the organic compound may not be necessary, increasing a throughput or efficiency of a manufacturing process of a semiconductor device.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A method of cleaning a semiconductor device comprising:
forming an oxide layer having an opening on a substrate;
forming a conductive layer in the opening;
removing the oxide layer using an etching solution including an organic compound; and
removing a residual organic compound adhered to the substrate and the conductive layer using an ozone solution.

2. The method of claim 1, wherein the etching solution includes a low ammonium liquid (LAL) solution including the organic compound, ammonium fluoride, hydrogen fluoride and water.

3. The method of claim 1, wherein the organic compound includes a metal corrosion inhibitor, a surfactant or a combination thereof.

4. The method of claim 1, further comprising performing a first rinsing process using deionized water, after removing the oxide layer.

5. The method of claim 1, wherein the ozone solution includes about 5 ppm to about 100 ppm of ozone.

6. The method of claim 1, wherein the ozone solution further includes about 0.001 percent-by-weight (% wt) to about 0.02 percent-by-weight (% wt) of hydrogen fluoride.

7. The method of claim 1, wherein removing the oxide layer and removing the residual organic compound are performed in-situ.

8. The method of claim 1, further comprising:
performing a second rinsing process using deionized water; and
performing a drying process using an isopropyl alcohol vapor, after removing the residual organic compound.

9. A method of manufacturing a semiconductor device comprising:
forming a mold layer pattern including an opening on a substrate;
forming a conductive layer in the opening and on the mold layer pattern;
forming a buffer layer on the conductive layer to fill the opening;
partially removing the buffer layer and the conductive layer pattern until the mold layer pattern is exposed to form a lower electrode and a buffer layer pattern in the lower electrode;
removing the mold layer pattern using an etching solution including an organic compound; and
removing a residual organic compound adhered to the lower electrode using an ozone solution.

10. The method of claim 9, wherein the organic compound includes a metal corrosion inhibitor, a surfactant or combination thereof.

11. The method of claim 9, wherein the ozone solution includes about 5 ppm to about 100 ppm of ozone.

12. The method of claim 9, wherein the ozone solution further includes about 0.001 percent-by-weight (% wt) to about 0.02 percent-by-weight (% wt) of hydrogen fluoride.

13. The method of claim 9, further comprising:
performing a rinsing process using deionized water; and
performing a drying process using an isopropyl alcohol vapor, after removing the residual organic compound adhered to the lower electrode.

14. The method of claim 9, wherein the buffer layer is formed using a material having an etching selectivity relative to an etching selectivity of the mold layer pattern.

15. The method of claim 14, wherein the buffer layer is formed using a photoresist.

16. The method of claim 9, wherein the lower electrode includes at least one selected from the group including tungsten, titanium, tungsten nitride and titanium nitride.

17. The method of claim 9, wherein the etching solution is a low ammonium liquid (LAL) solution including the organic compound, ammonium fluoride, hydrogen fluoride and water.

18. The method of claim 9, further comprising:
removing the buffer layer pattern, after removing the residual organic compound adhered to the lower electrode;
forming a dielectric layer on the lower electrode; and
forming an upper electrode on the dielectric layer.
